(19) United States
(12) Patent Application Publication
(10) Pub. No.: US 2008/0036332 A1
(43) Pub. Date: Feb. 14, 2008

(54) Diffusion device

(76) Inventors: Thomas A. Helf, New Berlin, WI (US); Edward L. Paas, Los Altos, CA (US)

Correspondence Address: S.C. JOHNSON & SON, INC., 1525 HOWE STREET, RACINE, WI, 53403-2236, US

(21) Appl. No.: 11/635,935

(22) Filed: Dec. 8, 2006

Related U.S. Application Data
(63) Continuation-in-part of application No. 11/464,419, filed on Aug. 14, 2006.

(51) Int. Cl. H01L 41/00

(52) U.S. Cl. 310/311

(57) ABSTRACT

A diffusion device includes a housing and a cavity disposed in a top portion of the housing, wherein the cavity is defined by a bottom wall. The device further includes a flame-shaped compartment extending upwardly through a first aperture in the bottom wall and is disposed within the cavity. A second aperture is disposed within the bottom wall and is spaced from the first aperture and a substance emitter is disposed within the housing, wherein the substance emitter is operable to dispense fluid through the second aperture.

### CROSS REFERENCE TO RELATED APPLICATIONS

This application is a continuation-in-part of U.S. application Ser. No. 11/464,419, filed Aug. 14, 2006, entitled “Drive Circuits and Methods for Ultrasonic Piezoelectric Actuators.”

### BACKGROUND OF THE INVENTION

1. Field of the Invention

The present invention relates to diffusion devices, and more particularly, to diffusion devices having a lighting effect.

2. Description of the Background of the Invention

Few things are quite as versatile at setting the ambience in an area as scented candles because of their wide array of shapes and sizes, as well as the seemingly limitless number of available scents. However, like any other candle, a scented candle must be used properly and with caution to avoid undesirable consequences.

Electronic lighting devices have been developed that mimic the appearance of a real candle. One device includes two side-by-side lamps that are turned on and off at such frequencies that a flickering effect is perceived. Similarly, another device includes circuitry to control two light bulbs in close proximity to each other such that the bulbs flicker. Moreover, the circuitry and bulbs are held within a container of a size and shape similar to common candles. While these devices may mimic the visual aesthetics of a candle, they fail to provide the scented candle experience, i.e., they fail to emit fragrance in addition to light.

Fragrance dispensers are also generally known. For example, it is known to emit fragrance from an aerosol container upon the activation of a trigger by a user. Also, other methods utilize the evaporative properties of liquids, or other vaporizable materials, to cause vapors with desired properties to be distributed into the ambient air. For example, one fragrance dispenser includes a glass container containing a fluid into which a porous nylon wick extends. The wick extends outwardly from the glass container to disperse fragrance into the surrounding atmosphere with or without the use of a heater, fan, etc. Further volatile releasing devices are disclosed in Denen et al., U.S. Pat. No. 6,296,196, filed Mar. 6, 2000, and entitled “Control system for atomizing liquids with a piezoelectric vibrator” and Martens, III, et al., U.S. Pat. No. 7,017,829, filed Apr. 14, 2003, and entitled “Atomizer wicking system” the disclosures of which are hereby incorporated by reference herein. Although these devices provide fragrance emission, they do not provide the visual aesthetic of a candle.

### SUMMARY OF THE INVENTION

According to one aspect of the present invention, a diffusion device includes a housing and a cavity disposed in a top portion of the housing, wherein the cavity is defined by a bottom wall. The device further includes a flame-shaped compartment extending upwardly through a first aperture in the bottom wall and is disposed within the cavity. A second aperture is disposed within the bottom wall and is spaced from the first aperture and a substance emitter is disposed within the housing, wherein the substance emitter is operable to dispense fluid through the second aperture.

According to another aspect of the present invention, a diffusion device includes a housing and a support member disposed within the housing for supporting a printed circuit board (PCB) and a light emitting diode (LED). The device further includes a flame-shaped actuator extending from the housing, wherein the LED is disposed within the flame-shaped actuator. A switch is operatively connected to the PCB and is disposed adjacent the flame-shaped actuator, wherein pressure on the flame-shaped actuator actuates the switch to turn the LED on or off.

According to yet another aspect of the present invention, a kit comprises a diffusion device having a housing and a first base portion wherein the housing is adapted to selectively engage the first base portion. The kit further includes a second base portion wherein the housing is adapted to selectively engage the second base portion.

Other aspects and advantages of the present invention will become apparent upon consideration of the following detailed description.

### BRIEF DESCRIPTION OF THE DRAWINGS

FIG. 1 is a top isometric view of a first embodiment of a diffusion device;

FIG. 2 is an exploded isometric view of the diffusion device of FIG. 1;

FIG. 2A is a bottom isometric view of a top portion of the diffusion device of FIG. 1;

FIG. 3 is a cross-sectional view taken generally along the lines 3-3 of FIG. 1;

FIG. 4 is a view similar to FIG. 1 showing the diffusion device thereof with a top portion removed;

FIG. 5 is a view similar to FIG. 4 with a second support member rotated upwardly to reveal components disposed below the second support member including a printed circuit board;

FIG. 5A is a view similar to FIG. 5 with the printed circuit board removed therefrom;

FIG. 6 is a top isometric view of the diffusion device of FIG. 1 illustrating an opposite side thereof;

FIG. 7 is a bottom isometric view of the diffusion device of FIG. 1 with a bottom portion removed therefrom;

FIG. 8 is an exploded view of a piezoelectric actuator contained within the diffusion device of FIG. 1;

FIG. 9 is a top isometric view of a replaceable fluid reservoir for insertion into any of the embodiments of a diffusion device herein;

FIGS. 10A, 10B, and 10C are elevational views of the diffusion device of FIG. 1 with various interchangeable base portions;

FIG. 11 is an exploded isometric view similar to FIG. 2 of a second embodiment of a diffusion device; and

FIG. 12 is a top isometric view of the diffusion device of FIG. 11 with a second support member rotated upwardly to reveal components disposed below the second support member including a printed circuit board.

Throughout the figures, like or corresponding reference numerals have been used for like or corresponding parts.

### DETAILED DESCRIPTION OF THE PREFERRED EMBODIMENTS

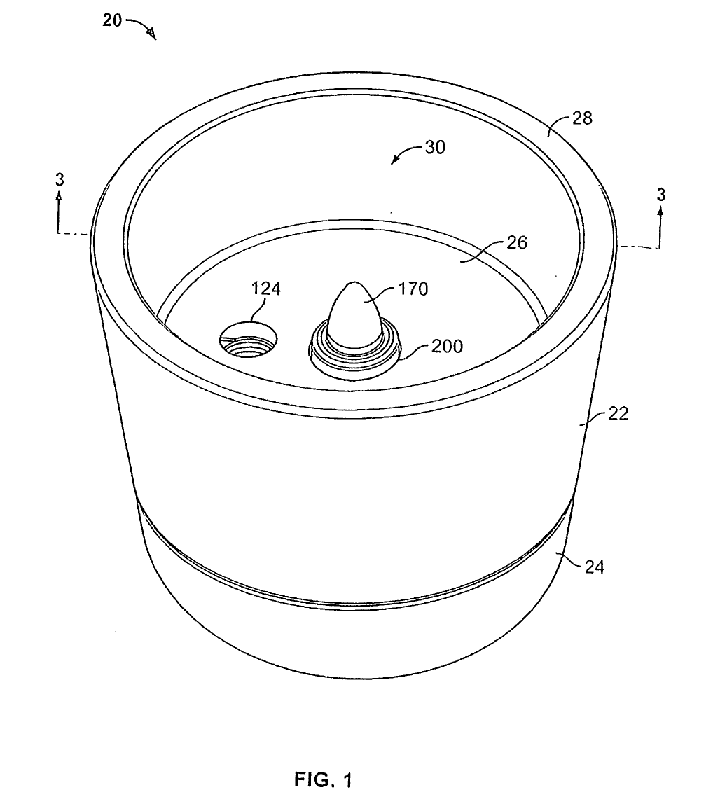

As depicted in FIGS. 1-7, a diffusion device 20 includes a top portion 22 and a bottom base portion 24. The top portion 22 includes a horizontal wall 26 and a cylindrical wall 28 extending upwardly from and horizontal wall 26 to form a cavity 30.

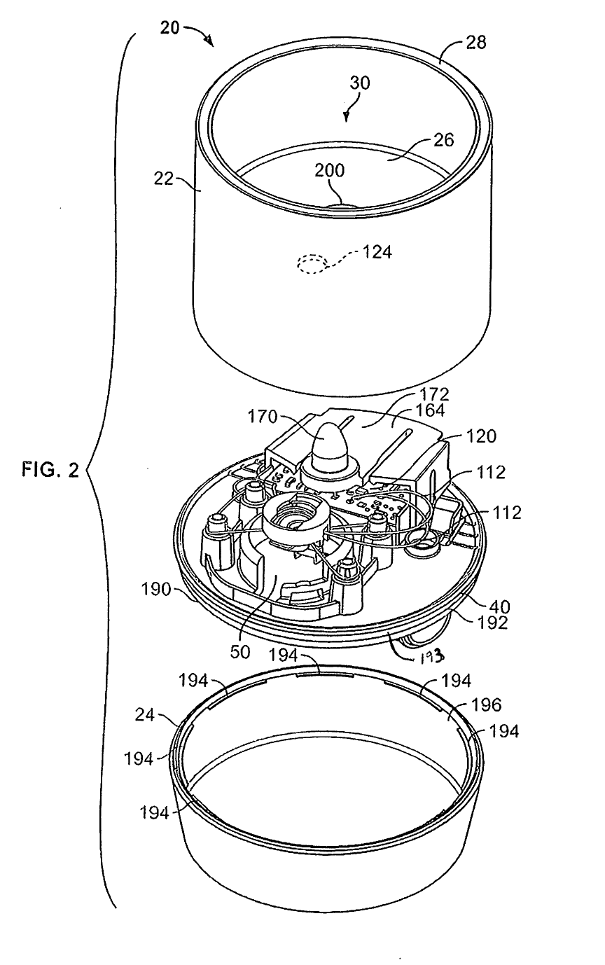

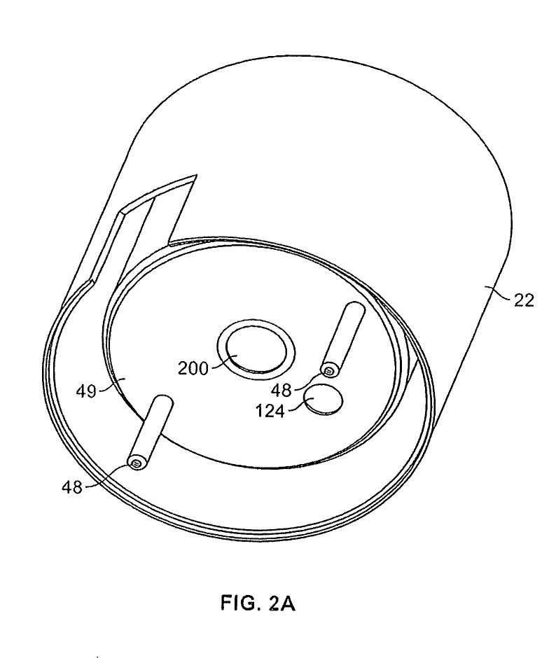

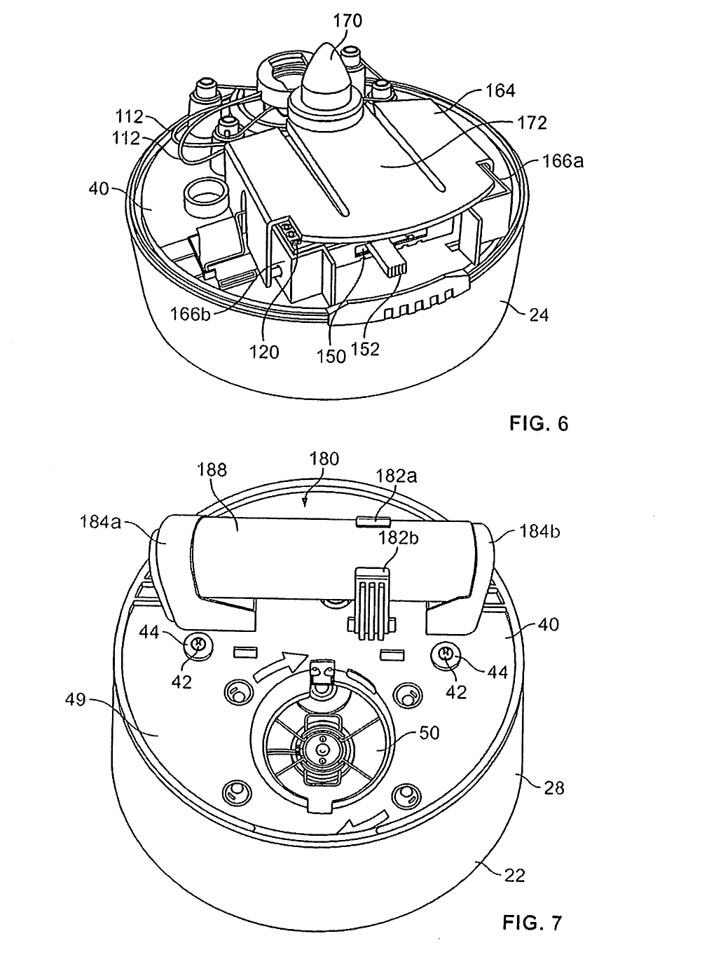

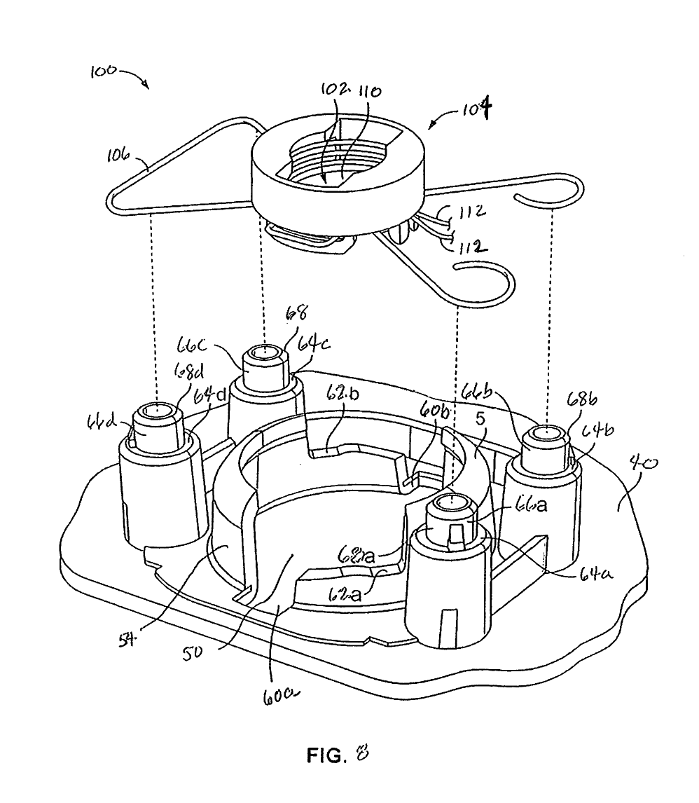

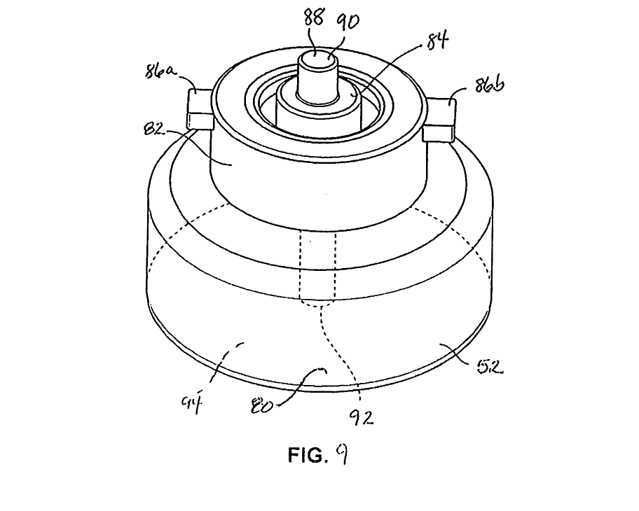

A support member 40 is disposed between the top portion 22 and the base portion 24 and is secured to the top portion 22 by two or more screws 42 that extend upwardly through holes 44 in the support member 40 and into threaded posts 48 that extend downwardly from a bottom surface 49 of the horizontal wall 26 (see, particularly, FIGS. 2A and 7). The support member 40 is formed with an opening 50 therein that receives a replaceable fluid reservoir 52, as seen in FIGS. 3 and 9. As best seen in FIG. 8, a bottle support 54 that forms a part of the support member 40 includes an upwardly extending cylindrically shaped reservoir mounting wall 56. The mounting wall 56 includes two opposing bayonet slots 60a, 60b formed therein and walls 62a, 62b defining corresponding circumferentially extending detents forming a part of the bayonet slots 60a, 60b, respectively. Four cylindrical mounting posts 64a-64d extend upwardly from the support member 40 adjacent the mounting wall 56 wherein each mounting post 64a-64d includes a smaller projection 66a-66d extending upwardly from a top portion 68a-68d thereof. The fluid reservoir 52 is removably inserted into the diffusion device 20, as discussed in detail hereinafter.

The fluid reservoir 52 includes an active material in liquid form therein, wherein the active material is preferably a fragrance. Alternatively, the active material may be an insecticide, an insect repellant, an insect attractant, a disinfectant, a sanitizer, an air purifier, an aromatherapy scent, an antiseptic, an odor eliminator, an air-freshener, a deodorizer, or any other active ingredient(s) that are usefully dispersed into the air.

As shown in FIG. 9, the fluid reservoir 52 comprises a transparent cylindrical container 80 with a neck 82. A combination plug and wick holder 84 is affixed to the neck 82, wherein the plug and wick holder 84 includes a pair of laterally extending mounting lugs 86a, 86b. A wick 88 is disposed within the reservoir 52 in contact with fluid therein. An upper end 90 of the wick 88 extends beyond the neck and a lower end 92 of the wick 88 is disposed within the reservoir 52 toward a bottom surface 94 thereof. The wick 88 transfers liquid by capillary action from within the reservoir 52 to the upper end 90 of the wick 88. The fluid reservoir 52 is inserted into the support member 40 by aligning the lugs 86a, 86b with the bayonet slots 60a, 60b, respectively, and pushing the reservoir 52 upwardly, thereby inserting the lugs 86a, 86b into the respective bayonet slots 60a, 60b. The reservoir 52 is thereafter rotated to force the lugs 86a, 86b to engage with the walls 62a, 62b defining the detent portions of the respective bayonet slots 60a, 60b to secure the reservoir 52 within the diffusion device 20.

Referring next to FIG. 8, a piezoelectric actuator 100 includes a piezoelectric element 102 and orifice plate assembly 104 similar or identical to those described in Denen et al., U.S. Pat. No. 6,296,196, filed Mar. 6, 2000, and entitled “Control system for atomizing liquids with a piezoelectric vibrator,” Martens, III, et al., U.S. Pat. No. 7,017,829, filed Apr. 14, 2003, and entitled “Atomizer wicking system,” and Helf et al., U.S. Pat. No. 6,896,193, filed Nov. 11, 2002, entitled “Atomizer with improved wire type atomizing element support and method of making same,” owned by the assignee of the present application and the disclosure of which is hereby incorporated by reference herein. The actuator 100 is mounted on the mounting posts 64a-64d by a metal support wire 106 that extends through the actuator 100 and around the mounting posts 64a-64d. The orifice plate assembly 104 comprises an orifice plate 110, wherein an outer circumferential portion of the orifice plate 110 is in contact with the piezoelectric actuator 100. Perforations extend through the orifice plate 110.

The piezoelectric element 102 is connected by wires 112 to a printed circuit board (PCB) 120 (FIGS. 2, 4, 5, 6, and 8), discussed in greater detail hereinafter. The wires 112 supply an alternating voltage produced by circuitry disposed on the PCB 120 to opposite sides of the piezoelectric actuator 100. A diameter of the actuator 100 alternately increases and decreases in size when the alternating voltage is applied to the piezoelectric actuator 100, thereby causing the orifice plate 110 to vibrate up and down due to the contact of the actuator 80 with the orifice plate 110. The orifice plate 110 is, in turn, in contact with fluid supplied by the wick 88. The up and down vibration of the orifice plate 110 causes liquid to be driven through the perforations in the orifice plate 110 and the liquid is emitted upwardly in the form of aerosolized particles. The particles traverse an unobstructed interior 122 (FIG. 3) of the top portion 22 and pass through a first aperture 124 in the horizontal wall 26 of the top portion 22.

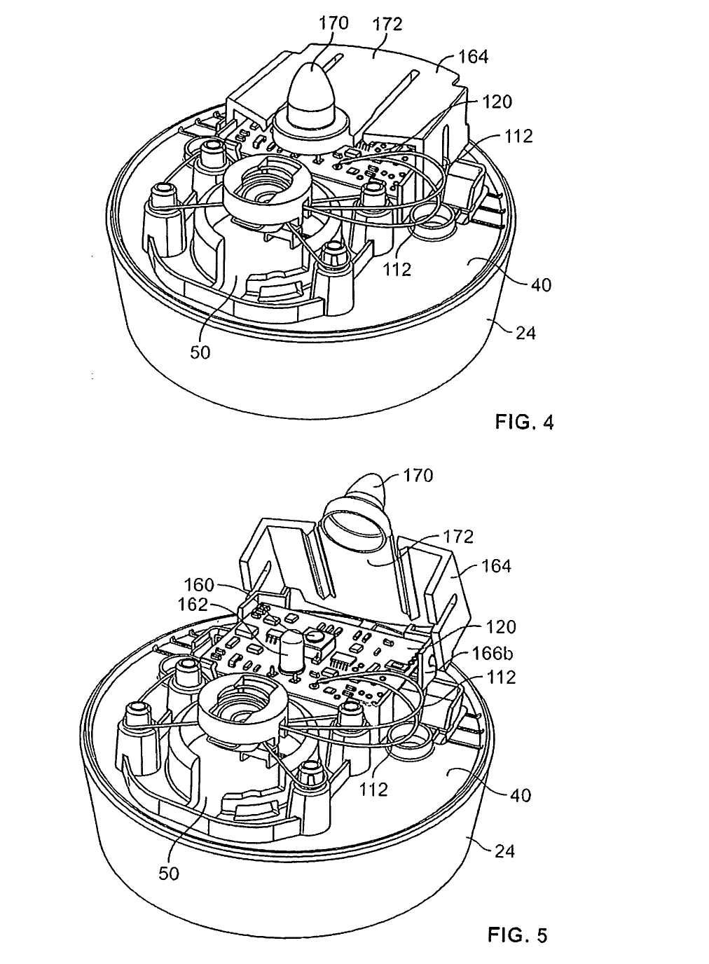

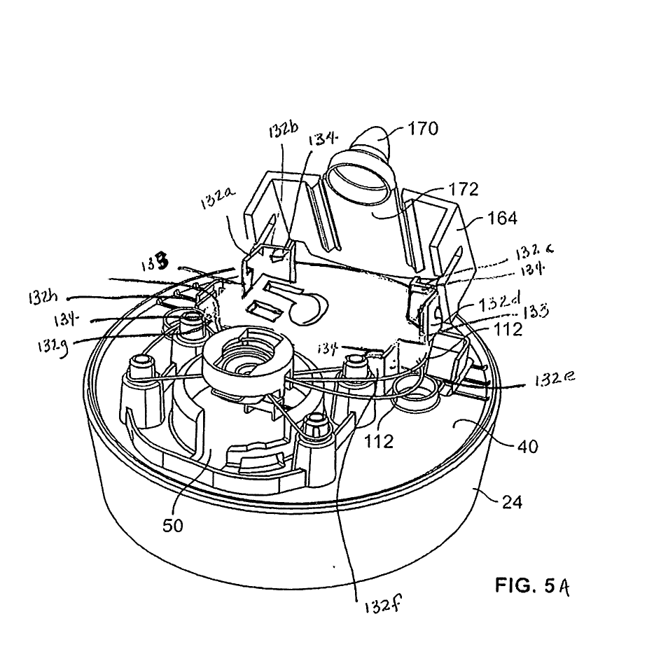

As best seen in FIGS. 3 and 5A, the PCB 120 is mounted on retention members 132a-132h. The retention members 132a, 132d, 132e, and 132h include shoulder portions 133 extending outwardly therefrom at a first height. The retention members 132b, 132c, 132f, and 132g include finger portions 134 extending outwardly therefrom and disposed at a second height that is greater than the first height. The difference between the second and first heights is about the same as a thickness of the PCB 120 such that the PCB 120 snaps between over the shoulder portions 133 to be retained in position between the shoulder portions 133 and the finger portions 134. As seen specifically in FIGS. 3 and 6, the PCB 120 includes a slide switch 150 having a button 152 extending outwardly therefrom. The button 152 is movable to one of five detent positions, which are discussed in greater detail hereinafter. Optionally, the button 152 may be movable to any number of selectable positions. The position of the slide switch 150 is detected by circuitry mounted on the PCB 120 to control the operating mode and emission frequency of the diffusion device 20.

As seen in FIG. 5, a further switch 160 extends upwardly from and is operatively connected to the PCB 120. A light emitting diode (LED) 162 also extends upwardly from and is operatively connected to the PCB 120 and is spaced from the switch 160. A second support member 164 is hingedly connected to the retention members 132a, 132d that aid in supporting the PCB 120 on the support member 40. A hinged, hollow, translucent, and flame-shaped actuator 170 is disposed atop the PCB 120 such that the LED 162 extends into the actuator 170 and a flexure 172 connecting the actuator 170 to the second support member 164 carried by the first-named support member 40 is in contact with the switch 160. Pressure exerted downwardly on the flame-shaped actuator 170 causes the flexure 172 to trigger the switch 160, as discussed in greater detail hereinafter.

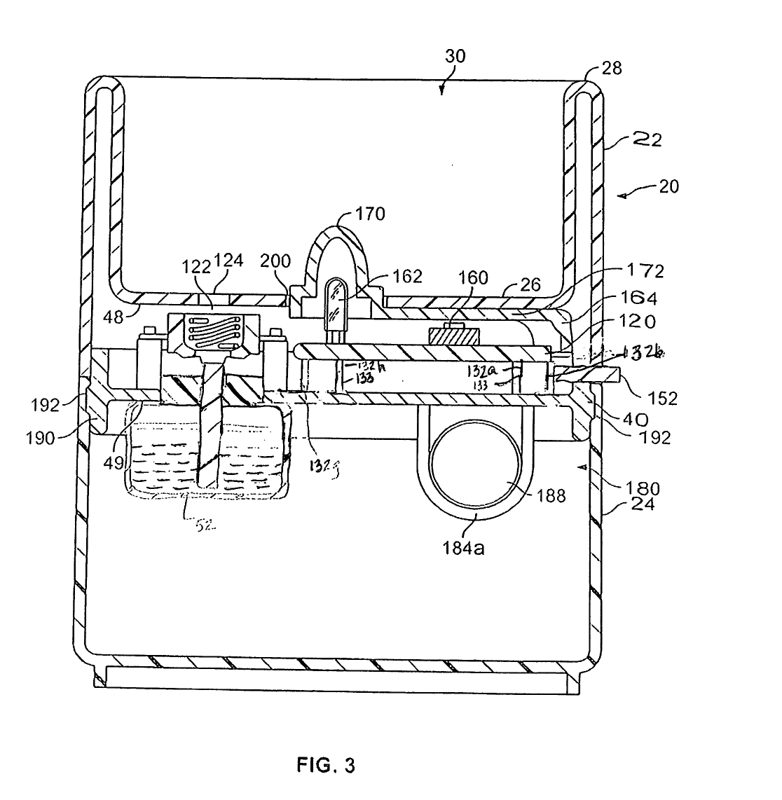

The second support member 164 is hinged to allow the second support member 164 to be rotated from a closed position to an open position. FIG. 5 illustrates the second support member 164 in the open position wherein the PCB 120, switch 160, and LED 162 are accessible and the LED 162 is no longer disposed within the flame-shaped actuator 170. As seen in FIGS. 2 and 4, the PCB 120, switch 160, and LED 162 are not accessible and the flame-shaped actuator 170 is disposed over the LED 162 when the second support member 164 is in the closed position.

As seen in FIGS. 3 and 7, the support member 40 further includes a battery holder 180 including retention fingers 182a, 182b and end contact members 184a, 184b extending from the bottom surface 149 of the support member 40. The battery holder 180 is adapted to receive a single 1.5 volt AA alkaline-manganese dioxide battery 188 and includes contacts for supplying an electrical voltage to the PCB 120. If desired, the single AA battery may be replaced by any number of other batteries or another power source.

The support member 40 also includes an annular plate 190, as seen in FIG. 2, that extends downwardly from the support member 40 away from the top portion 22. The plate 190 includes a continuous radially outwardly-directed flange 192 extending outwardly from the plate 190 that is spaced from the support member 40 to form a channel 195. The base portion 24 includes a plurality of circumferential protrusions 194 extending radially inwardly from an inner surface 196 thereof. The support member 40 fits atop the base portion 24 by snapping the protrusions 194 into the channel 193 to create an interference fit between the protrusions 194 and the flange 192. Optionally, any other known means for attaching two mechanical components may be utilized, such as a bayonet mount, an interference fit, etc.

Referring to FIGS. 1-3, when the support member 40 and top portion 22 are attached, the flame-shaped actuator 170 extends through a second aperture 200 in the horizontal wall 26 forming the top portion 22 and the piezoelectric actuator 100 is disposed below the first-named aperture 124 in the horizontal wall 26. The first-named aperture 124 is positioned such that when the piezoelectric actuator 100 is triggered by the PCB 120, active material in the fluid reservoir 52 is dispensed into the atmosphere through the first-named aperture 124.

In operation, a battery 180 is inserted into the diffusion device 20 to begin operation of the device 20. Thereafter, the user depresses the flame-shaped actuator 170, thereby forcing the flexure 172 downwardly into contact with the button 152 and activating the switch 160. Activation of the switch 160 a first time turns the LED 162 on and also activates a “boost” function. The PCB 120 preferably implements programming to create a flickering effect in the LED 162 when the LED 162 is on and the “boost” function consists of the diffusion device 20 activating the piezoelectric actuator 100 at a rapid pace or in a greater volume to fill the surroundings with the active material. After a “boost” period has expired, the device begins emitting active material in a normal fashion, wherein 12 millisecond bursts of active material occur at intervals selectable by the slide switch 150. Triggering the switch 160 a second time causes the LED 162 to turn off. Preferably, although not necessarily, the piezoelectric actuator 100 does not turn off.

In one embodiment, the “boost” function consists of emitting active material in a group of ten 12 millisecond pulses, wherein each group of ten pulses lasts for 720 millisecond. Each group of ten 12 millisecond pulses is repeated every sixty seconds. Preferably, the “boost” period is between about 1 minute and about 10 minutes, more preferably between about 2 minutes and about 8 minutes, and most preferably about 5 minutes.

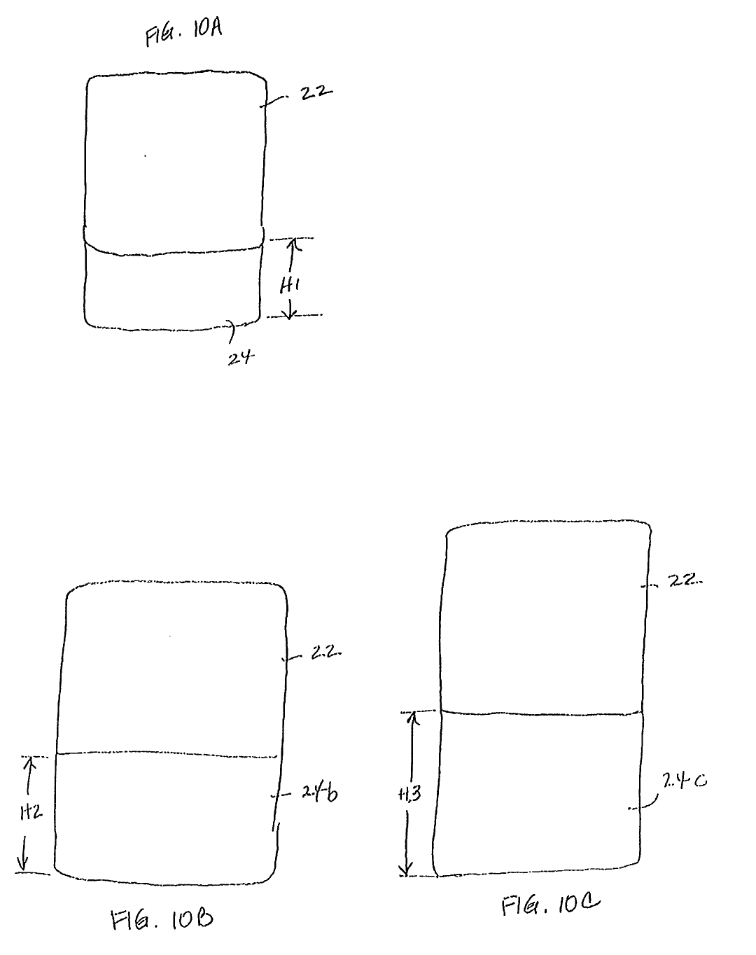

As seen in FIGS. 10A-10C, the top portion 22 is selectively engageable and usable with any of a plurality of base portions 24. In particular, the base portion 24 of FIG. 10A having a height H1 can be used with the top portion 22 or other base portions 24b, 24c may be so used having heights H2, H3, respectively. The heights H1, H2, and H3 are preferably substantially different so that different aesthetics are obtained. Alternatively, different base portions 24 may have different colors, designs, shapes, and/or other features to create different diffusion devices 20. Optionally, the diffusion device 20 may be provided in a kit with one or more base portions 24, such that the diffusion device 20 may be used with any of such base portions 24 to create different imitation candles. In such an embodiment, the kit preferably includes at least one diffusion device 20 and one or more base portions 24 for use with the at least one diffusion device 20. In another embodiment, multiple diffusion devices 20 with a same number of base portions 24 of differing heights could be used to emulate a pillar candle arrangement with multiple candles.

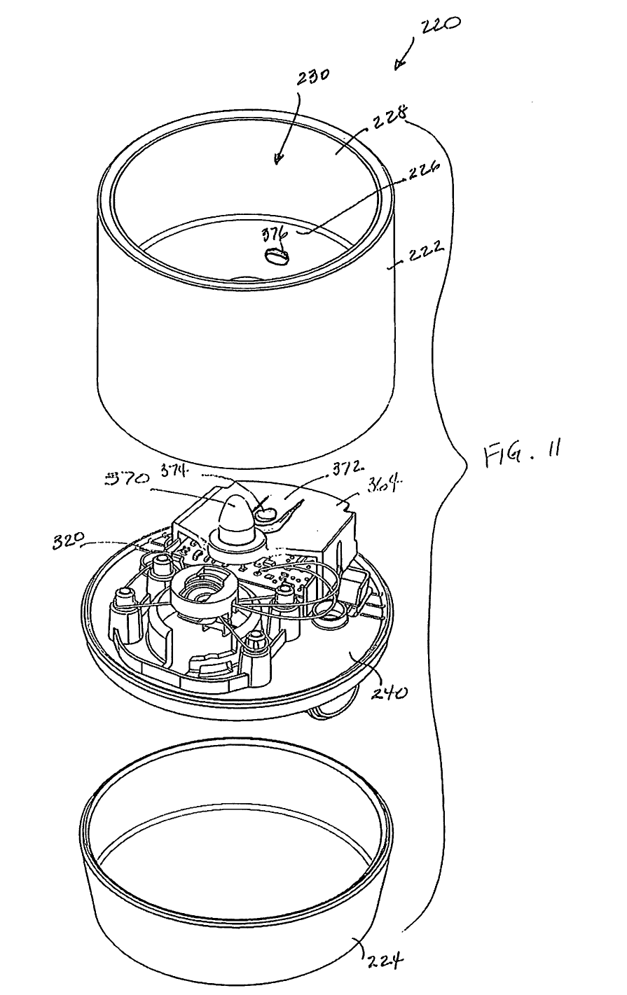

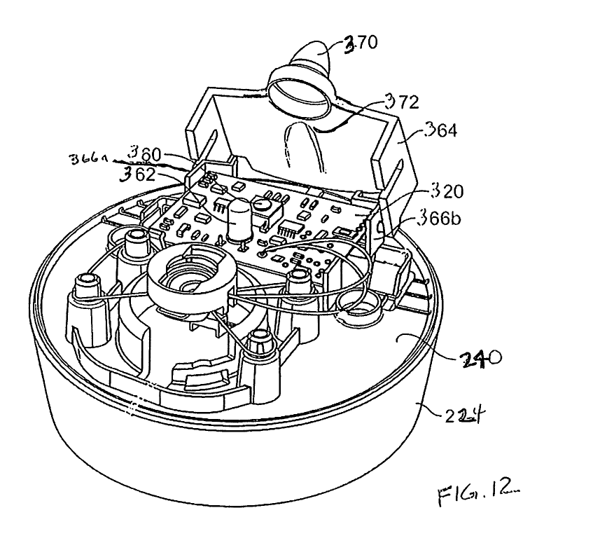

Another embodiment of a diffusion device 220 is depicted in FIGS. 11 and 12. The diffusion device 220 is similar to the diffusion device 20 of FIGS. 1-7, except for the method of activation of the diffusion device 220. In particular, the diffusion device 220 includes a top portion 222 and a bottom base portion 224, wherein the top portion 222 includes a horizontal wall 226 and a cylindrical wall 228 extending upwardly from the horizontal wall 226 to form a cavity 230. The diffusion device 220 includes a support member 240 that is identical to the support member 40 of FIGS. 1-7 and includes the same components attached thereto.

A PCB 320 is supported by the support member 240, as described in detail above, wherein a switch 360 extends upwardly from and is operatively connected to the PCB 320. An LED 362 also extends upwardly from and is operatively connected to the PCB 320 and is spaced from the switch 360. A second support member 364 is hingedly connected to the opposing retention members 366a, 366b. A hollow, translucent, and flame-shaped compartment 370 is disposed atop the PCB 320 such that the LED 362 extends into the compartment 370. A flexure 372 is connected to the second support member 374 and is in contact with the switch 360. The flexure 372 includes a contact member 374 extending upwardly therefrom, wherein the contact member 374 extends through a first aperture 376 in the horizontal wall 226. Pressure exerted downwardly on the contact member 374 causes the flexure 372 to trigger the switch 360. Upon actuation of the switch 360, the LED 362 and the “boost” feature are activated, as discussed in detail above. In all other aspects, the diffusion device 220 is identical to the diffusion device 20 of FIGS. 1-7.

Any of the drive circuits or portions of the drive circuits disclosed in Blandino et al. U.S. patent application Ser. No. 11/464,419, filed Aug. 14, 2006, and entitled “Drive Circuits and Methods for Ultrasonic Piezoelectric Actuators,” may be implemented within the PCB 320 of any of the embodiments of diffusion devices disclosed herein, the disclosure of which is hereby incorporated by reference.

### INDUSTRIAL APPLICABILITY

The diffusion device of the present invention provides light and/or active material emitters. The device provides an overall desired aesthetic ambience in an area, such as a room.

Numerous modifications to the present invention will be apparent to those skilled in the art in view of the foregoing description. Accordingly, this description is to be construed as illustrative only and is presented for the purpose of enabling those skilled in the art to make and use the invention and to teach the best mode of carrying out same. The exclusive rights to all modifications which come within the scope of the appended claims are reserved.

We claim:

1. A diffusion device, comprising:
a housing;
a cavity disposed in a top portion of the housing, wherein the cavity is defined by a bottom wall;
a flame-shaped compartment extending upwardly through a first aperture in the bottom wall and disposed within the cavity;
a second aperture disposed within the bottom wall and spaced from the first aperture; and
a substance emitter disposed within the housing, wherein the substance emitter is operable to dispense fluid through the second aperture.

2. The diffusion device of claim 1, wherein the body is cylindrical in shape.

3. The diffusion device of claim 1, wherein the substance emitter includes a piezoelectric actuator comprising a piezoelectric element and orifice plate assembly.

4. The diffusion device of claim 1, further including a bottom portion having a support member that supports a printed circuit board (PCB) and the substance emitter.

5. The diffusion device of claim 4, further including a light emitting diode coupled to the PCB and extending into the flame-shaped compartment.

6. The diffusion device of claim 5, further including a switch coupled to the PCB.

7. The diffusion device of claim 6, wherein the flame-shaped compartment is disposed atop the PCB such that a flexure connecting the flame-shaped compartment to a second support member carried by the first-named support member is in contact with the switch.

8. The diffusion device of claim 7, wherein the flame-shaped compartment acts as an actuator in that pressure exerted downwardly on the flame-shaped compartment causes the flexure to trigger the switch.

9. The diffusion device of claim 8, wherein activation of the switch a first time turns the LED on and activates a boost function of the substance emitter and activation of the switch a second time turns the LED off.

10. The diffusion device of claim 7, further including a flexure formed by the second support member, wherein a distal end of the flexure includes a contact member that, when pressure is exerted downwardly on the contact member, the flexure allows downward movement of the contact member to trigger the switch.

11. The diffusion device of claim 1, further including a bottom portion disposed below the top portion and wherein the bottom portion includes a base portion that is removable and replaceable with another base portion.

12. A diffusion device, comprising:
a housing;
a support member disposed within the housing for supporting a printed circuit board (PCB) and a light emitting diode (LED);
a flame-shaped actuator extending from the housing, wherein the LED is disposed within the flame-shaped actuator; and
a switch operatively connected to the PCB and disposed adjacent the flame-shaped actuator;
wherein pressure on the flame-shaped compartment actuates the switch to turn the LED on or off.

13. The diffusion device 12, further including a substance emitter disposed within the housing and operatively connected to the circuit board, wherein the substance emitter includes a piezoelectric actuator comprising a piezoelectric element and orifice plate assembly.

14. The diffusion device of claim 13, wherein the flame-shaped actuator is disposed atop the PCB such that a flexure connecting the flame-shaped actuator to a second support member carried by the first-named support member is in contact with the switch.

15. The diffusion device of claim 14, wherein pressure exerted downwardly on the flame-shaped actuator causes the flexure to trigger the switch.

16. The diffusion device of claim 15, wherein actuation of the switch a first time turns the LED on and activates a boost function of the substance emitter and actuation of the switch a second time turns the LED off.

17. The diffusion device of claim 12, wherein the housing includes a top portion which houses the circuit board, the LED, the flame-shaped actuator, and the switch, and a bottom portion disposed below the top portion and wherein the bottom portion includes a base portion that is removable replaceable with another base portion.

18. A kit, comprising:
a diffusion device having a housing;
a first base portion, wherein the housing is adapted to selectively engage the first base portion; and
a second base portion, wherein the housing is adapted to selectively engage the second base portion.

19. The kit of claim 18, wherein the diffusion device includes a printed circuit board (PCB) disposed within the housing and a light emitting diode (LED) operatively connected to the PCB.

20. The kit of claim 19, wherein the diffusion device further includes a substance emitter disposed within the housing and operatively connected to the PCB.
